(19) United States
(12) Patent Application Publication
(10) Pub. No.: US 2015/0037615 A1
(43) Pub. Date: Feb. 5, 2015

(54) ELECTRONIC DEVICE AND POLARITY-SAFE STRUCTURE CONFIGURED TO RECEIVE A BATTERY

(71) Applicants: AMBIT MICROSYSTEMS (SHANGHAI) LTD., Shanghai (CN); HON HAI PRECISION INDUSTRY CO., LTD., New Taipei (TW)

(72) Inventors: JIAN-FENG XIAO, Shanghai (CN); BIN HUANG, Shanghai (CN)

(21) Appl. No.: 14/444,303

(22) Filed: Jul. 28, 2014

(30) Foreign Application Priority Data
Jul. 31, 2013 (CN) 2013204656701

(51) Int. Cl. H01R 13/64; H01M 2/34; H05K 5/02

(52) U.S. Cl. CPC H01R 13/64; H05K 5/0247; H01M 2/342; H01M 2200/30
USPC 429/1; 439/680

(57) ABSTRACT

An electronic device ensuring the polarity-correct installation of a battery includes a polarity-safe structure. The polarity-safe structure includes a fixing member located in a fixing groove and an elastic member secured in a receiving groove opposite to the fixing member. The battery cathode can be electrically coupled to the elastic member, but while the battery anode can be coupled to the fixing member, it cannot couple to the elastic member.

### FIELD

The present disclosure relates to the structure of battery-powered electronic device.

### BACKGROUND

Batteries are widely used in electronic devices, such as flashlight, remote control. When a battery is loaded into an electronic device with anode and cathode of the battery reversed, it would cause damage to the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an embodiment of a polarity-safe structure.

FIG. 2 is an isometric view of a battery assembled with a fixing member and an elastic member of the polarity-safe structure of FIG. 1.

FIG. 3 is a cross sectional view of a battery received in the polarity-safe structure of FIG. 1.

FIG. 4 is another cross sectional view of the battery received in the polarity-safe structure of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series and the like.

The following disclosure describes an electronic device and a polarity-safe structure.

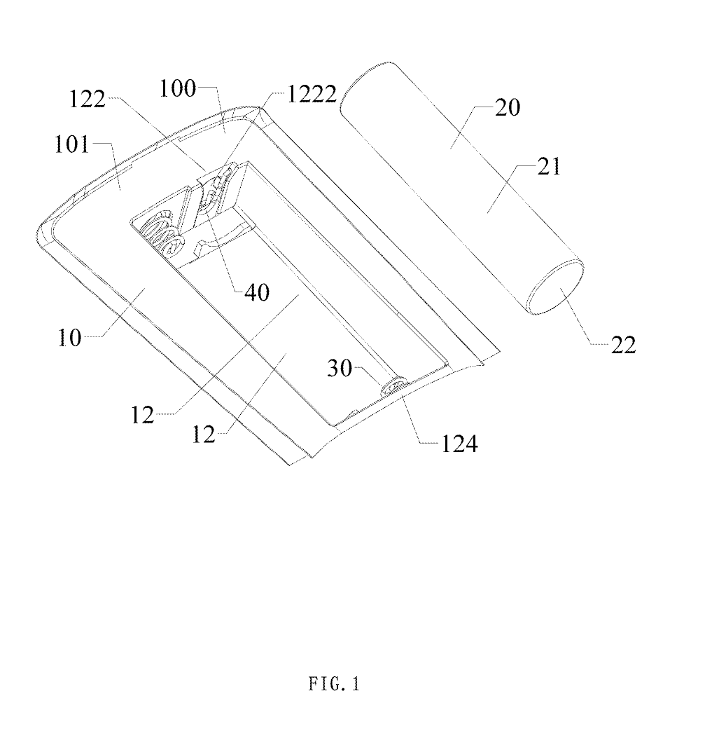

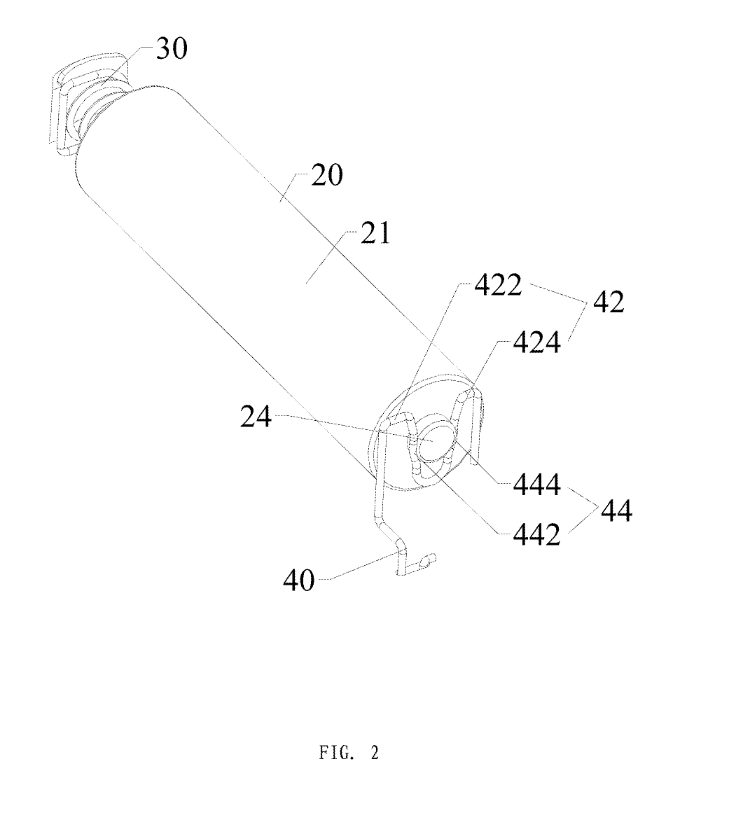

FIG. 1 and FIG. 2 illustrate a polarity-safe structure 10. The polarity-safe structure 10 is configured to mount a battery 20 to an electronic device 100.

In at least one embodiment, the polarity-safe structure 10 includes an enclosure 101 defining two receiving grooves 12. A positive end 122 and a negative end 124 are fixed in the enclosure 101 and located at opposite ends of each receiving groove 12. The battery 20 is received in the receiving groove 12. The positive end 122 defines a fixing groove 1222 communicating with the receiving groove 12. A size of the fixing groove 1222 is smaller than a size of the cathode 22 and is bigger than a size of the anode 24.

The battery 20 includes a body 21, a cathode 22 and an anode 24. The cathode 22 and the anode 24 are positioned at opposite ends of the body 20.

The polarity-safe structure 10 further includes a fixing member 40 and an elastic member 30. The fixing member 40 is received in the fixing groove 1222, and the elastic member is positioned at the negative end 124.

The fixing member 40 includes a first fixing member 442, a second fixing member 444, and a positioning part 42. An end of the first fixing member 442 and an end of the second fixing member 444 are coupled together to form a holder 44. The holder 44 is U-shaped. In at least one embodiment, the holder can be V-shaped. The positioning part 42 includes a first positioning end 422 and a second positioning end 424. The first positioning end 422 extends from the other end of the first fixing member 442. The second positioning end 424 extends from the other end of the second fixing member. The fixing member 40 is secured in the fixing groove 1222 by the first positioning end 422 and the second positioning end 424.

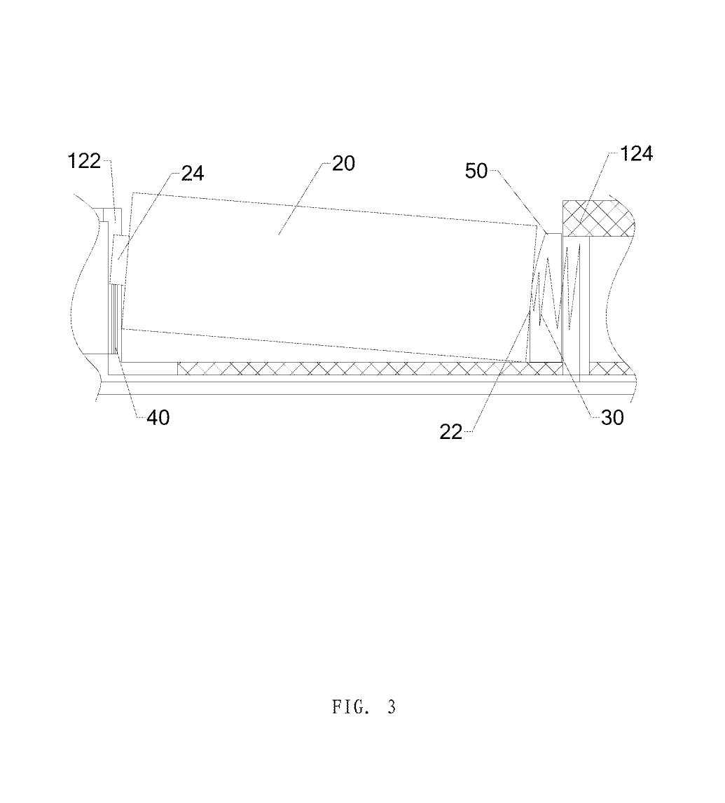

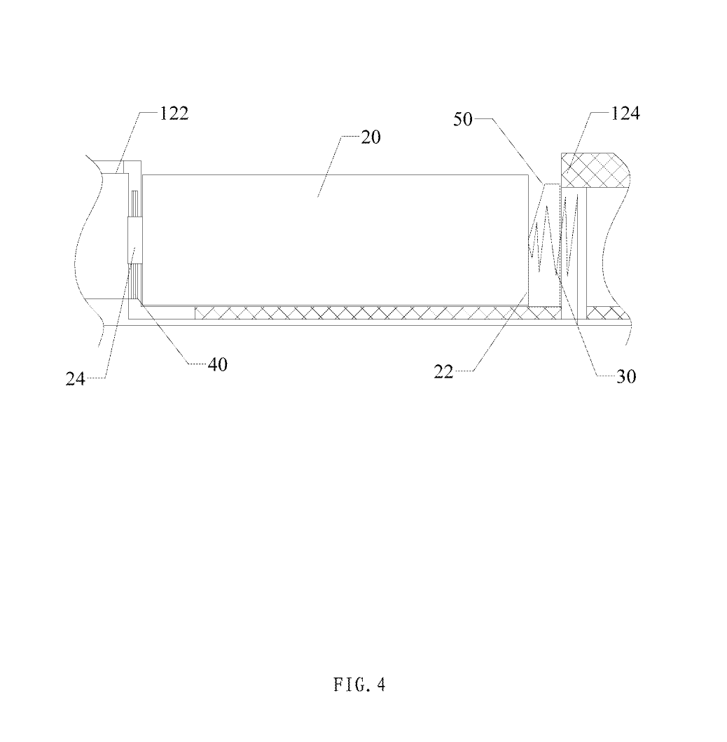

FIG. 3 and FIG. 4 illustrate that the polarity-safe structure 10 further includes a positioning protrusion 50. The positioning protrusion 50 protrudes from the negative end 124, and is adjacent to the elastic member 30.

In operation, the battery 20 is loaded into the receiving groove 12. The anode 24 is inserted into the fixing groove 1222 and is clamped by the holder 44. The elastic member 30 is compressed by the cathode 22, and the positioning protrusion 50 abuts the battery 20. If the battery 20 has been loaded into the receiving groove 12 in such a way that the cathode 22 abuts the positive end 122, and the anode 24 abuts the negative end 124, the cathode 22 is not able to make an electrical connection with the electronic device 100.

The embodiments shown and described above are only examples. Many details are often found in the art such as the other features of an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A polarity-safe structure configured to receive a battery, the polarity-safe structure comprising:
an enclosure defining a receiving groove to receive the battery;
a positive end located at one end of the receiving groove;
a negative end located at an opposite end of the receiving groove from the positive end;
a fixing groove defined in the positive end, wherein a size of the fixing groove is configured to be smaller than a cathode of the battery;
a fixing member located in the fixing groove and configured to electrically couple to an anode of the battery; and
an elastic member secured to the negative end and configured to electrically couple to the cathode.

2. The polarity-safe structure of claim 1, wherein the fixing member comprises a holder and a positioning part, the positioning part extending from the holder, the fixing member being secured at the positive end by the positioning part.

3. The polarity-safe structure of claim 2, wherein the holder comprises a first fixing member and a second fixing member coupled with the first fixing member, the positioning part comprises a first positioning end extending from an end of the first fixing member and a second positioning end extending from an end of the second fixing member.

4. The polarity-safe structure of claim 3, wherein the holder is V-shaped.

5. The polarity-safe structure of claim 3, wherein the holder is U-shaped.

6. The polarity-safe structure of claim 3, wherein the polarity-safe structure further comprises a positioning protrusion, the protrusion is protruded from the negative end and is adjacent to the elastic member.

7. An electronic device, comprising:
a battery comprising a body, a cathode, and an anode, the cathode and the anode being positioned at two opposite ends of the body; and
a polarity-safe structure configured to mount the battery, comprising:
an enclosure, the enclosure defining a receiving groove;
a positive end and a negative end, the positive end and the negative end being located at opposite ends of the receiving groove;
a fixing groove defined in the positive end and communicating with the receiving groove;
a fixing member located in the fixing groove; and
an elastic member secured on the negative end;
wherein the positive end prevents the cathode from being inserted into the fixing groove to contact the fixing member, the body is received in the receiving groove with the anode being electrically coupled to the fixing member and the cathode being electrically coupled to the elastic member.

8. The electronic device of claim 7, wherein the fixing member comprises a holder and a positioning part, the positioning part extending from the holder, the anode is electrically coupled to the holder, the fixing member is secured at the positive end by the positioning part.

9. The electronic device of claim 8, wherein the holder comprises a first fixing member and a second fixing member coupled with the first fixing member, the positioning part comprises a first positioning end extending from an end of the first fixing member and a second positioning end extending from an end of the second fixing member.

10. The electronic device of claim 9, wherein the holder is V-shaped.

11. The electronic device of claim 9, wherein the holder is U-shaped.

12. The electronic device of claim 9, wherein the polarity-safe structure further comprises a positioning protrusion protruded from the negative end, the positioning protrusion is adjacent to the elastic member and resists the cathode.
